(19) United States
(12) Patent Application Publication
(10) Pub. No.: US 2012/0273921 A1
(43) Pub. Date: Nov. 1, 2012

(54) SEMICONDUCTOR DEVICE AND METHOD FOR FABRICATING THE SAME

(76) Inventors: Kwan-Woo DO, Gyeonggi-do (KR); Kee-Jeung Lee, Gyeonggi-do (KR); Kyung-Woong Park, Gyeonggi-do (KR); Kun-Hoon Baek, Gyeonggi-do (KR); Ji-Hoon Ahn, Gyeonggi-do (KR); Woo-Young Park, Gyeonggi-do (KR)

(21) Appl. No.: 13/334,048

(22) Filed: Dec. 21, 2011

(30) Foreign Application Priority Data
Apr. 29, 2011 (KR) 10-2011-0040775

(51) Int. Cl. H01L 29/92; H01L 21/02

(52) U.S. Cl. 257/532; 438/381; 438/386; 257/E29.343; 257/E21.011

(57) ABSTRACT

A semiconductor device includes a dielectric layer, where the dielectric layer includes a metal oxide layer, a metal nitride carbide layer including hydrogen therein, and a reduction prevention layer inserted between the metal nitride carbide layer and the dielectric layer.

### CROSS-REFERENCE TO RELATED APPLICATIONS

The present application claims priority of Korean Patent Application No. 10-2011-0040775, filed on Apr. 29, 2011, which is incorporated herein by reference in its entirety.

### BACKGROUND

1. Field

Exemplary embodiments of the present invention relate to fabrication technology of a nonvolatile memory device, and more particularly, to a semiconductor device and a method for fabricating the same.

2. Description of the Related Art

As the semiconductor devices are getting smaller in size to increase productivity during a fabrication process of DRAM, which is a representative semiconductor memory device, the area of a capacitor in DRAM and the capacitance of the capacitor are reduced. In order to address such a reduction, a dielectric layer having a high permittivity is introduced to increase the capacitance.

Here, however, a leakage current characteristic is degraded due to a low band gap of the dielectric layer. In order to address such a degradation, an electrode having a high work function is being developed. For example, a metal nitride carbide obtained by doping impurities for controlling a work function, for example, carbon into metal nitride which has been conventionally used as an electrode layer has been introduced.

FIG. 1 is a cross-sectional view of a capacitor of a conventional semiconductor device having a metal nitride carbide electrode.

Referring to FIG. 1, the capacitor of the conventional semiconductor device includes a dielectric layer 102 having a high permittivity and inserted between a lower electrode 101 and an upper electrode 103. The dielectric layer 102 having a high permittivity includes metal oxide such as titanium oxide (TiO₂) or hafnium oxide (HfO₂). Furthermore, the lower electrode 101 and the upper electrode 103 include a metal nitride carbide doped with impurities for controlling a work function to have a high work function. Due to an increase of the work function caused by carbon contained in the metal nitride carbide, a potential barrier is formed between the dielectric layer 102 and the metal nitride carbide, thereby improving a leakage current characteristic.

A method for fabricating an electrode layer having a high work function, that is, the metal nitride carbide in the conventional semiconductor device, includes depositing metal nitride using a metal organic precursor based on atomic layer deposition (ALD) or chemical vapor deposition (CVD) and doping carbon through a process of leaving a ligand attached to the metal organic precursor, for example, CH₃ in a thin film to improve process efficiency. During such a deposition process, it is difficult to prevent hydrogen as well as carbon for controlling a work function from remaining in the film.

Currently, as semiconductor devices are scaled down more and more, a dielectric layer 102 having a higher permittivity is useful. However, since hydrogen remains in the metal nitride carbide during the deposition process for carbon doping, the remaining hydrogen causes a thin layer 15 to be formed in the dielectric layer 102 at the interface between the dielectric layer 102 formed of metal oxide and the metal nitride carbide. In this case, a leakage current characteristic may rapidly deteriorate.

### SUMMARY

An embodiment of the present invention is directed to a semiconductor device capable of preventing the degradation of leakage current characteristic in a capacitor including a metal nitride carbide electrode, and a method for fabricating the same.

In accordance with an embodiment of the present invention, a semiconductor device includes: a dielectric layer, wherein the dielectric layer includes a metal oxide layer; a metal nitride carbide layer including hydrogen therein; and a reduction prevention layer inserted between the metal nitride carbide layer and the dielectric layer.

In accordance with another embodiment of the present invention, a method for fabricating a semiconductor device includes: forming a capping layer; forming a metal nitride carbide layer over the capping layer; forming a reduction prevention layer over the metal nitride carbide layer; and forming a dielectric layer including metal oxide over the reduction prevention layer.

In accordance with yet another embodiment of the present invention, a method for fabricating a semiconductor device includes: forming a mold layer over a substrate, wherein the mold layer has a storage node hole formed therein; forming a storage node in the storage node hole, wherein the storage node includes stacked layers of a first reduction prevention layer, a first metal nitride carbide layer, and a second reduction prevention layer; forming a dielectric layer along the storage node surface; and forming a plate electrode over the dielectric layer, wherein the plate electrode includes stacked layers of a third reduction prevention layer, a second metal nitride carbide layer, and a capping layer.

### BRIEF DESCRIPTION OF THE DRAWINGS

FIG. 1 is a cross-sectional view of a capacitor of a conventional semiconductor device having a metal nitride carbide electrode.

FIG. 2 is a cross-sectional view of a semiconductor device having a metal nitride carbide electrode in accordance with a first embodiment of the present invention.

FIG. 3 is a timing diagram showing the method for fabricating the semiconductor device having a metal nitride carbide electrode in accordance with the first embodiment of the present invention.

FIGS. 4A to 4I are cross-sectional views illustrating a method for fabricating a semiconductor device in accordance with a second embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

Exemplary embodiments of the present invention provide a semiconductor device, which is capable of substantially preventing the degradation of a leakage current characteristic due to a reduction/deoxidation of a dielectric layer caused by hydrogen contained in a metal nitride carbide in a capacitor of a semiconductor device in which the metal nitride carbide having a high work function is applied as an electrode, when a dielectric layer having a low band gap and a high permittivity is applied, and a method for fabricating the semiconductor device. In the embodiments of the present invention, a reduction prevention layer formed of metal nitride is inserted between the metal nitride carbide and the dielectric layer, thereby preventing the reduction of the dielectric layer caused by hydrogen within the metal nitride carbide and simultaneously securing a work function characteristic of the metal nitride carbide.

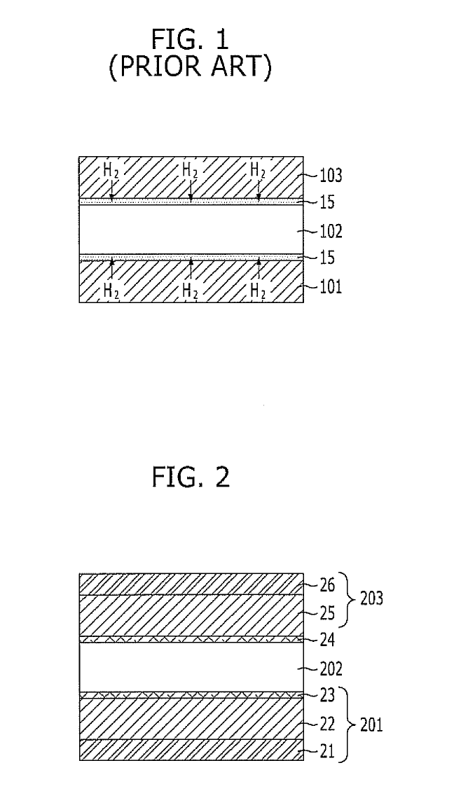

FIG. 2 is a cross-sectional view of a semiconductor device having a metal nitride carbide electrode in accordance with a first embodiment of the present invention. FIG. 2 illustrates the exemplary embodiment of the present invention is applied to a flat-plate capacitor.

Referring to FIG. 2, the semiconductor device in accordance with the first embodiment of the present invention has a structure in which a dielectric layer 202 having a high permittivity is inserted between a lower electrode 201 and an upper electrode 203. The lower electrode 201 has a structure in which a first capping layer 21, a first metal nitride carbide layer 22, and a first reduction prevention layer 23 are sequentially stacked, and the upper electrode 203 has a structure in which a second reduction prevention layer 24, a second metal nitride carbide layer 25, and a second capping layer 26 are sequentially stacked.

The dielectric layer 202 having a high permittivity refers to a dielectric layer having a larger dielectric constant than silicon oxide (SiO₂) and may include metal oxide such as tantalum oxide (Ta₂O₅), niobium oxide (Nb₂O₃), titanium oxide (TiO₂), hafnium oxide (HfO₂), hafnium silicon oxide (HfSiO₂), strontium titanium oxide (SrTiO₃), or barium strontium titanium oxide (BaSrTiO₃). The metal oxide having a high permittivity has a low band bap, as the dielectric constant increases.

The first and second metal nitride carbide layers 22 and 25 refer to a metal nitride into which impurities for controlling a work function, for example, carbon (C) are doped to prevent the degradation of leakage current characteristic of the dielectric layer 202 having a low band gap. Although will described below, the first and second metal nitride carbide layers 22 and 25 are deposited using a metal organic precursor based on ALD or CVD, and C (that is, impurities for controlling a work function) is doped by a method of leaving a ligand attached to the metal organic precursor, for example, CH₃ in a thin film during the deposition process, in order to increase the process efficiency. Therefore, hydrogen (H₂) as well as C remains in the film. For example, the first and second metal nitride carbide layers 22 and 25 including H₂ therein may include TiCHN.

The first and second capping layers 21 and 26 covering the exposed first and second metal nitride carbide layers 22 and 25 serve to prevent natural oxidation that occurs because the first and second metal nitride carbide layers 22 and 25 including H₂ have a lower density than metal nitride due to impurities such as H₂ and C. The first and second capping layers 21 and 26 include metal nitride. For example, the first and second capping layers 21 and 26 may include TiN.

The first and second reduction/deoxidation prevention layers 23 and 24 inserted between the dielectric layer 202 and the first and second metal nitride carbide layers 22 and 25, respectively, serve to prevent the dielectric layer 202 formed of metal oxide from being reduced by H₂ contained in the first and second metal nitride carbide layers 22 and 25, thereby preventing a rapid degradation of a leakage current characteristic. That is, the first and second reduction prevention layers 23 and 24 serve to prevent H₂ within the first and second metal nitride carbide layers 22 and 25 from diffusing into and reacting with the dielectric layer 202, and include metal nitride. For example, the first and second reduction prevention layers 23 and 24 may include TiN.

According to an example, the first and second reduction prevention layers 23 and 24 may have such a dense film quality as to prevent the diffusion of H_{z}. For example, when the first and second reduction prevention layers 23 and 24 are formed of the same material as the first and second capping layers 21 and 26, the first and second reduction prevention layers 23 and 24 may have a denser film quality (e.g., having less pores) than the first and second capping layers 21 and 26.

Furthermore, the first and second reduction prevention layers 23 and 24 may secure such a thickness as to prevent the diffusion of H₂ and simultaneously have no effect upon an electrical characteristic (that is, work function) of the first and second metal nitride carbide layers 22 and 25. When the thicknesses of the first and second reduction prevention layers 23 and 24 are decreased to a designated thickness or less, the first and second reduction prevention layers 23 and 24 may not effectively prevent the reduction of the dielectric layer 202 caused by H₂. Furthermore, when the thicknesses of the first and second reduction prevention layers 23 and 24 are increased to a designated thickness or more, it is difficult to secure the electrical characteristic of the first and second metal nitride carbide layers 22 and 25. For example, the first and second reduction prevention layers 23 and 24 may have a thickness of 5 Å to 30 Å.

In accordance with the first embodiment of the present invention, the first and second reduction prevention layers 23 and 24 are inserted between the dielectric layer 202 and the first and second metal nitride carbide layers 22 and 25 including H₂, respectively, thereby preventing the degradation of leakage current characteristic caused by H₂.

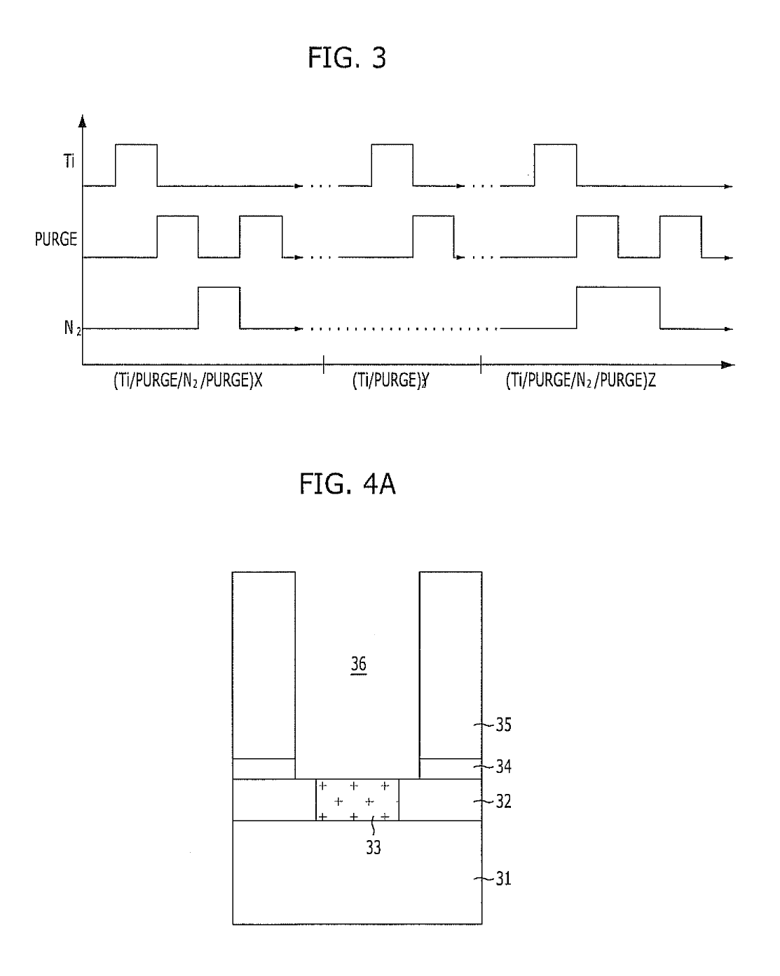

Hereinafter, referring to FIGS. 2 and 3, a method for fabricating the semiconductor device having a metal nitride carbide electrode in accordance with the first embodiment of the present invention will be described. Here, according to an example, the first and second capping layers 21 and 26, the first and second metal nitride carbide layers 22 and 25 including H₂, and the first and second reduction prevention layers 23 and 24 are formed of TiN, TiCHN, and TiN, respectively, by using ALD.

FIG. 3 is a timing diagram showing the method for fabricating the semiconductor device having a metal nitride carbide electrode in accordance with the first embodiment of the present invention.

Referring to FIGS. 2 and 3, a first capping layer 21 including TiN is formed. The first capping layer 21 is formed by repeating a unit cycle X times. The unit cycle includes a Ti organic precursor injection step represented by ‘Ti’, a purge step represented by ‘purge’, a nitrogen injection step represented by ‘N₂’, and a purge step, that is, (Ti/purge/N_{z}/purge). According to the repetition number X of the unit cycle, the thickness of the first capping layer 21 may be controlled.

The Ti organic precursor injection step means a step of supplying a Ti organic precursor into a chamber, and the Ti organic precursor is adsorbed to the surface of a deposition target by the supplying of the Ti organic precursor. The Ti organic precursor may include TEMAT{Tetrakis(ethylmethylamino)titanium, Ti[N(C₂H₅)CH₃]₄}, TDMAT{Tetrakis(dimethylamino)titanium, Ti(N(CH₃)₂)₄} and TDEAT{Tetrakis(diethylamino)titanium, Ti[N(C₂H₅)₂]₄}. The Ti organic precursor injection step may use helium gas (He) as carrier gas at a flow rate of 500 sccm to 1,000 sccm, and may be performed at a temperature of 200° C. to 400° C. The purge step means a step of removing the residual Ti organic precursor after the adsorption, and inert gas which does not react with the Ti organic precursor is used as purge gas. The purge gas may be supplied at a flow rate of 300 sccm to 2,000 sccm. The N₂ injection step means a step of supplying a reactant and forming a TiN layer through a reaction between the reactant and the adsorbed Ti organic precursor. The reactant may include N₂ gas activated by plasma. According to an example, the reactant may be activated by remote plasma. When the remote plasma is used, the already formed structure may be prevented from being physically damaged by plasma. The remote plasma may be formed using a power of 2,000 W to 3,000 W, the N₂ gas may be supplied at a flow rate of 100 sccm to 4,000 sccm, and the reaction time may be set to 1 to 5 seconds. The subsequent purge step means a step of removing reaction byproducts and the reactant remaining after the reaction. The purge gas may include inert gas, and may be supplied at a flow rate of 300 sccm to 2,000 sccm.

A first metal nitride carbide layer 22 including TiCHN is formed over the first capping layer 21. The first metal nitride carbide layer 22 may be in-situ formed in the same chamber as the first capping layer 21. The first metal nitride carbide layer 22 is formed by repeating a unit cycle Y times. The unit cycle includes a Ti organic precursor injection step and a purge step, that is, (Ti/purge). According to the number Y of the unit cycle, the thickness of the first metal nitride carbide layer 22 may be controlled.

The Ti organic precursor injection step means a step of supplying a Ti organic precursor into the chamber, and a Ti organic precursor is adsorbed to the surface of the first capping layer 21 by supplying the Ti organic precursor. The Ti organic precursor may include TEMAT{Ti[N(C₂H₅)CH₃]₄}, TDMAT{Ti(N(CH₃)₂)₄}, and TDEAT{Ti[N(C₂H₅)₂]₄}. The Ti organic precursor injection step may use He as carrier gas at a flow rate of 500 sccm to 1,000 sccm, and may be performed at a temperature of 200° C. to 400° C. The purge step means a step of removing the residual Ti organic precursor after the adsorption, and inert gas which does not react with the Ti organic precursor is used as the purge gas. The purge gas may be supplied at a flow rate of 300 sccm to 2,000 sccm. Here, the first metal nitride carbide layer 22 is formed through thermal decomposition of the Ti organic precursor, in order to dope impurities for controlling a work function, that is, C into a thin film. That is, since C is doped in such a manner that a ligand within the Ti organic precursor remains in the thin film, H₂ remains in the thin film at the same time as C for controlling a work function is doped into the thin film.

A first reduction prevention layer 23 including TiN is formed over the first metal nitride carbide layer 22 including H₂ therein. The first reduction prevention layer 23 may be in-situ formed in the same chamber as the first metal nitride carbide layer 22. The first reduction prevention layer 23 may be formed by repeating a unit cycle Z times. The unit cycle includes a Ti organic precursor injection step, a purge step, an N₂ injection step, and a purge step, that is, (Ti/purge/N₂/purge). According to the repetition number Z of the unit cycle, the thickness of the first reduction prevention layer 23 may be controlled.

The Ti organic precursor injection step means a step of supplying a Ti organic precursor into the chamber, and the Ti organic precursor is adsorbed to the surface of the first metal nitride carbide layer 22 by the supplying of the Ti organic precursor. The Ti organic precursor may include TEMAT{Ti[N(C₂H₅)CH₃]₄}, TDMAT{Ti(N(CH₃)₂)₄}, and TDEAT{Ti[N(C₂H₅)₂]₄}. The Ti organic precursor injection step may use He as carrier gas at a flow rate of 500 sccm to 1,000 sccm, and may be performed at a temperature of 200° C. to 400° C. The purge step means a step of removing the residual Ti organic precursor after the adsorption, and inert gas that does not react with the Ti organic precursor is used as purge gas. The purge gas may be supplied at a flow rate of 300 sccm to 2,000 sccm. The N₂ injection step means a step of supplying a reactant and forming a TiN layer through a reaction between the reactant and the adsorbed Ti organic precursor. The reactant may include N₂ gas activated by plasma. According to an example, the reactant may be activated by remote plasma. When the remote plasma is used, it is difficult to prevent the already formed structure from being physically damaged by plasma. At this time, in order to form a first reduction prevention layer 23 having a dense film quality, the remote plasma may be generated by using a power of 3,500 W to 6,000 W, and the reaction time may be set to 6 to 20 seconds. That is, in order to form the first reduction prevention layer 23 having a denser film quality than the first capping layer 21, the remote plasma power and the reaction time are further increased than during the formation process of the first capping layer 21. Furthermore, N₂ gas may be supplied at a low rate of 100 sccm to 4,000 sccm. The subsequent purge step means a step of removing reaction byproducts and the reactant remaining after the reaction. The purge gas may include inert gas and may be supplied at a flow rate of 300 sccm to 2,000 sccm.

Through the above-described processes, a lower electrode 201 in which the first capping layer 21, the first metal nitride carbide layer 22, and the first reduction prevention layer 23 are sequentially stacked (TiN/TiCHN/TiN) may be formed.

A dielectric layer 202 having a high permittivity is formed over the lower electrode 201, and an upper electrode 203 is formed in the same manner as the formation process of the lower electrode 201. The upper electrode 203 includes a second reduction prevention layer 24, a second metal nitride carbide layer 25, and a second capping layer 26, which are sequentially stacked (TiN/TiCHN/TiN).

The semiconductor device fabricated through the above-described processes includes the first and second reduction prevention layers 23 and 24 inserted between the dielectric layer 202 and the first and second metal nitride carbide layers 22 and 25 including H₂ therein, thereby preventing the reduction of the dielectric layer 202 caused by H₂ within the first and second metal nitride carbide layers and 25. Accordingly, the degradation of leakage current characteristic caused by H₂ within the first and second metal nitride carbide layers 22 and 25 may be prevented.

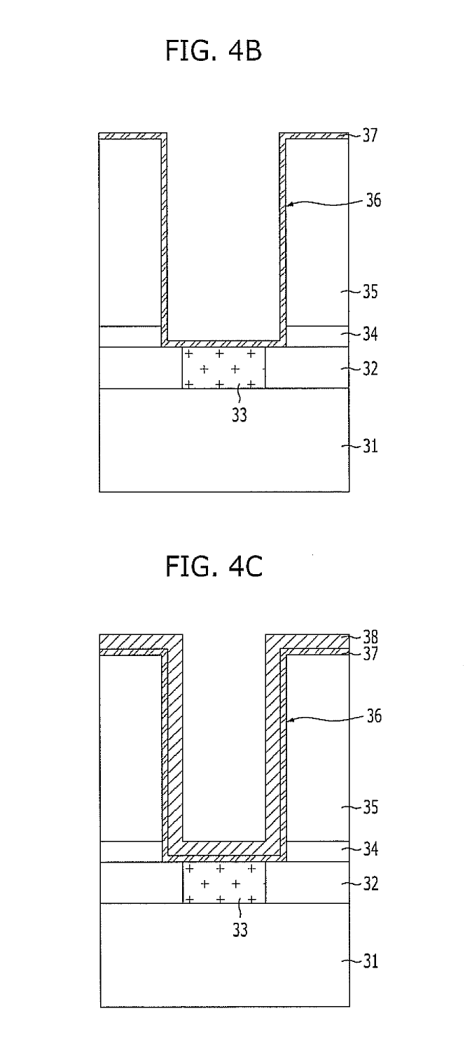

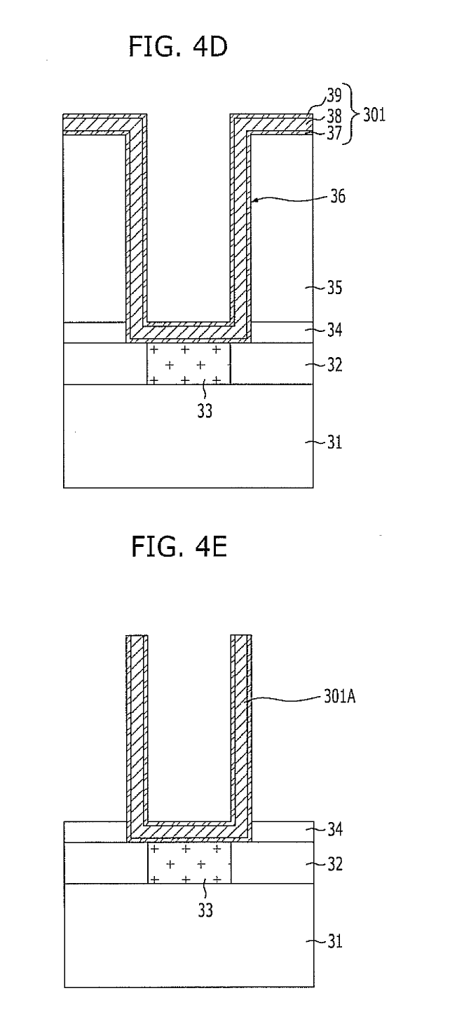

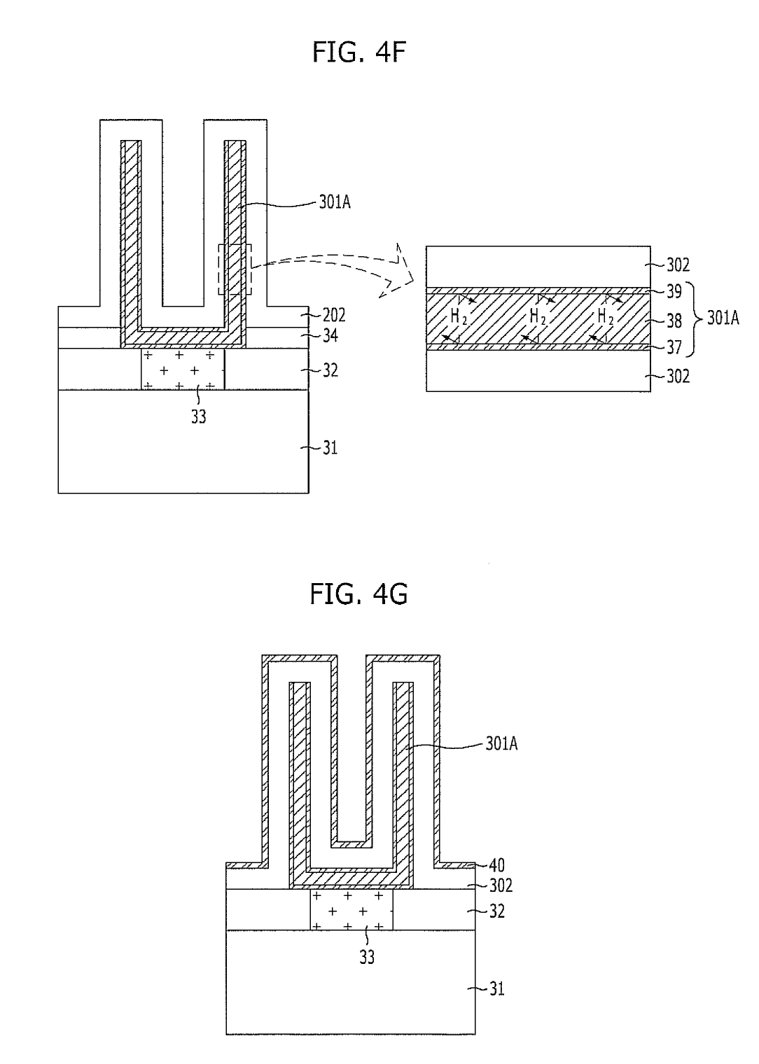

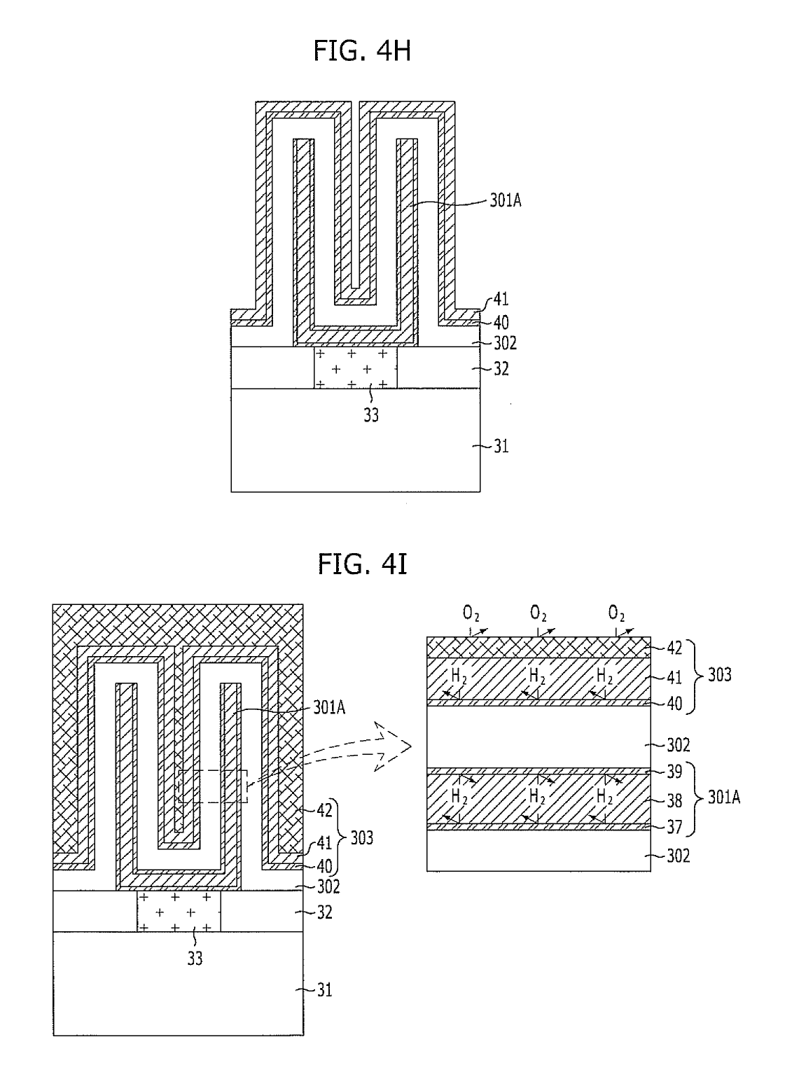

FIGS. 4A to 4I are cross-sectional views illustrating a method for fabricating a semiconductor device in accordance with a second embodiment of the present invention. FIGS. 4A to 4I illustrate a case in which the technical idea of the present invention is applied to a semiconductor device having a cylinder-type storage node.

Referring to FIG. 4A, an interlayer dielectric layer 32 is formed over a substrate 31 having a desired structure formed therein, and a storage node contact plug 33 is formed through the interlayer dielectric layer 32.

An etch stop layer 34 and a mold layer 35 are sequentially formed over the interlayer dielectric layer 32. The etch stop layer 34 is formed of a material having an etching selectivity with the interlayer dielectric layer 32 and the mold layer 35.

The mold layer 35 and the etch stop layer 34 are selectively etched to form a storage node hole 36 exposing the storage node contact plug 33.

Referring to FIG. 4B, a first reduction prevention layer 37 is formed along the surface of the structure including the storage node hole 36. The first reduction prevention layer 37 serves to prevent a reduction caused by H₂ between a storage node and a dielectric layer contacted with an outer wall of the storage node.

The first reduction prevention layer 37 may be formed of metal nitride, for example, TiN. When the first reduction prevention layer 37 is formed of TiN, the first reduction prevention layer 37 may be formed by repeating a unit cycle a plurality of times through ALD. The unit cycle includes a Ti organic precursor injection step, a purge step, an N₂ injection step, and a purge step, that is, (Ti/purge/N₂/purge). According to the repetition number of the unit cycle, the thickness of the first reduction prevention layer 37 may be controlled. In order to prevent the diffusion and reaction of H₂ and simultaneously secure an electrical characteristic of a metal nitride carbide layer formed through a subsequent process, the first reduction prevention layer 37 may be formed to a thickness of 5 Å to 30 Å.

Referring to FIG. 4C, a first metal nitride carbide layer 38 is formed over the first reduction prevention layer 37. The first metal nitride carbide layer 38 may be in-situ formed in the same chamber as the first reduction prevention layer 37. The first metal nitride carbide layer 38 serves as a substantial storage node, and may include a metal nitride into which impurities for controlling a work function, for example, C are doped to prevent the degradation of leakage current characteristic of the dielectric layer when the dielectric layer having a high permittivity is applied to secure capacitance.

The first metal nitride carbide layer 38 may be formed of TiCHN. In this case, the first metal nitride carbide layer 38 may be formed by repeating a unit cycle a plurality of times through ALD. The unit cycle includes a Ti organic precursor injection step and a purge step, that is, (Ti/purge). According to the repetition number of the unit cycle, the thickness of the first metal nitride carbide layer 38 may be controlled. At this time, the first metal nitride carbide layer 38 is formed through thermal decomposition of the Ti organic precursor, in order to dope impurities for controlling a work function, that is, C into a thin film. Since C is doped in such a manner that a ligand within the Ti organic precursor remains in a thin film, H₂ remains in the thin film at the same time as C for controlling a work function is doped into the thin film.

Referring to FIG. 4D, a second reduction prevention layer 39 is formed over the first metal nitride carbide layer 38. The second reduction prevention layer 39 may be in-situ formed in the same chamber as the first metal nitride carbide layer 38. The second reduction prevention layer 39 serves to prevent a reduction caused by H₂ between the storage node and the dielectric layer contacted with an inner wall of the storage node.

The second reduction prevention layer 39 may be formed to a thickness of 5 Å to 30 Å, and may be formed in the same manner as the first reduction prevention layer 37.

Accordingly, a storage node conductive layer 301 including the first reduction prevention layer 37, the first metal nitride carbide layer 38, and the second reduction prevention layer 39, which are sequentially stacked, may be formed.

Referring to FIG. 4E, an isolation process for the storage node conductive layer 301 is performed to form a storage node 301A inside the storage node hole 36.

The mold layer 35 is removed to expose the outer walls of the storage node 301A.

Referring to FIG. 4F, a dielectric layer 302 is formed along the surface of the structure including the storage node 301A. The dielectric layer 302 may be formed of a material having a high permittivity to obtain an adequate capacitance of a capacitor within a limited area.

The dielectric layer 302 may include metal oxide such as tantalum oxide (Ta₂O₅), niobium oxide (Nb₂O₃), titanium oxide (TiO₂), hafnium oxide (HfO₂), hafnium silicon oxide (HfSiO₂), strontium titanium oxide (SrTiO₃), or barium strontium titanium oxide (BaSrTiO₃). Since the metal oxide having a high permittivity has a low band bap as the dielectric constant increases, the leakage current characteristic may be degraded. However, since the storage node 301A includes the first metal nitride carbide layer 38 having a high work function, the degradation of leakage current characteristic caused by a potential barrier formed therebetween may be prevented.

Furthermore, since the storage node 301A includes the first and second reduction prevention layers 37 and 39, the first and second reduction prevention layers 37 and 38 block the reduction of the dielectric layer 302 through the diffusion and reaction of H₂ within the first metal nitride carbide layer 38 into and with the dielectric layer 302. Therefore, the degradation of leakage current characteristic which occurs as oxidation of the dielectric layer 302 is reduced by H₂.

Referring to FIG. 4G, a third reduction prevention layer 40 is formed over the dielectric layer 302. The third reduction prevention layer 40 serves to block H₂ within subsequently formed the metal nitride carbide layer (e.g., 41 in FIG. 4H) from diffusing into and reacting with the dielectric layer 302, like the first and second reduction prevention layers 37 and 39. The third reduction prevention layer 40 may be formed of metal nitride, for example, TiN, and may have a thickness of 5 Å to 30 Å. The third reduction prevention layer 40 may be formed according to the same method as the first and second reduction prevention layers 37 and 39.

Referring to FIG. 4H, a second metal nitride carbide layer 41 is formed over the third reduction prevention layer 40. The second metal nitride carbide layer 41 may be in-situ formed in the same chamber as the third reduction prevention layer 40. The second metal nitride carbide layer 41 serves as a substantial plate electrode, and may include a metal nitride into which impurities for controlling a work function, for example, C are doped to prevent the degradation of leakage current characteristic of the dielectric layer, which occurs when the dielectric layer having a high permittivity is applied to secure capacitance. The second metal nitride carbide layer 41 may be formed of TiCHN and may be formed according to the same method as that of the first metal nitride carbide layer 38.

Referring to FIG. 4I, a capping layer 42 is formed on the entire surface of the structure including the second metal nitride carbide layer 41. The capping layer 42 may be in-situ formed in the same chamber as the second metal nitride carbide layer 41. The capping layer 42 serves to prevent natural oxidation of the second metal nitride carbide layer 41 having a lower density than metal nitride, due to impurities such as H₂ and C.

The capping layer 42 may be formed of metal nitride and may be formed of the same material as the first to third reduction prevention layers 37, 39, and 40. That is, the capping layer 42 may be formed of TiN. In this case, the capping layer 42 may be formed by repeating a unit cycle a plurality of times through ALD. The unit cycle includes a Ti organic precursor injection step, a purge step, an N₂ injection step, and a purge step, that is, (Ti/purge/N₂/purge). According to the repetition number of the unit cycle, the thickness of the capping layer 42 may be controlled.

Accordingly, a plate electrode 303 having a structure in which the third reduction prevention layer 40, the second metal nitride carbide layer 41, and the capping layer 42 are stacked may be formed.

The semiconductor device formed through the above-described processes includes the reduction prevention layer formed between the dielectric layer and the metal nitride carbide, thereby preventing the degradation of leakage current characteristic caused by the reduction of the dielectric layer due to H₂ within the metal nitride carbide.

While the present invention has been described with respect to the specific embodiments, it will be apparent to those skilled in the art that various changes and modifications may be made without departing from the spirit and scope of the invention as defined in the following claims.

What is claimed is:

1. A semiconductor device comprising:
a dielectric layer, wherein the dielectric layer includes a metal oxide layer;
a metal nitride carbide layer including hydrogen therein; and
a reduction prevention layer inserted between the metal nitride carbide layer and the dielectric layer.

2. The semiconductor device of claim 1, further comprising a capping layer covering the metal nitride carbide.

3. The semiconductor device of claim 2, wherein the reduction prevention layer comprises the same material as the capping layer but has a film that is denser than the capping layer.

4. The semiconductor device of claim 1, wherein the reduction prevention layer comprises metal nitride.

5. The semiconductor device of claim 1, wherein the metal nitride carbide layer including H₂ therein comprises TiCHN and the reduction prevention layer comprises TiN.

6. A method for fabricating a semiconductor device, comprising:
forming a capping layer;
forming a metal nitride carbide layer over the capping layer;
forming a reduction prevention layer over the metal nitride carbide layer; and
forming a dielectric layer including metal oxide over the reduction prevention layer.

7. The method of claim 6, wherein the capping layer, the metal nitride carbide layer, and the reduction prevention layer are in-situ formed in the same chamber.

8. The method of claim 6, wherein the capping layer and the reduction prevention layer comprise metal nitride.

9. The method of claim 6, wherein the capping layer and the reduction prevention layer comprise TiN.

10. The method of claim 8, wherein the forming of the capping layer and the forming of the reduction prevention layer comprise:
injecting a metal organic precursor such that the metal organic precursor is adsorbed on a deposition target surface;
purging non-reacted metal organic precursor;
forming metal nitride through a reaction between the adsorbed metal organic precursor and a reactant; and
purging non-reacted reactant.

11. The method of claim 10, wherein the reactant comprises nitrogen gas activated by remote plasma.

12. The method of claim 11, wherein the capping layer and the reduction prevention layer are formed of the same material and have a denser film quality than the capping layer.

13. The method of claim 12, wherein, in the forming of the reduction prevention layer, the remote plasma is generated using a higher power than in the forming of the capping layer.

14. The method of claim 12, wherein, in the forming of the reduction prevention layer, the reaction between the metal organic precursor and the reactant is performed during a longer time than in the forming of the capping layer.

15. The method of claim 6, wherein the forming of the metal nitride carbide layer comprises:
injecting a metal organic precursor such that the metal organic precursor is adsorbed on a deposition target surface; and
purging the non-reacted metal organic precursor.

16. The method of claim 15, wherein, in the injecting of the metal organic precursor,
the metal organic precursor is thermally decomposed to form a metal nitride carbide layer such that a ligand within the metal organic precursor remains in the layer.

17. The method of claim 16, wherein the ligand comprises carbon and hydrogen.

18. The method of claim 6, wherein the metal nitride carbide layer comprises TiCHN.

19. A method for fabricating a semiconductor device, comprising:
forming a mold layer over a substrate, wherein the mold layer has a storage node hole formed therein;
forming a storage node in the storage node hole, wherein the storage node includes stacked layers of a first reduction prevention layer, a first metal nitride carbide layer, and a second reduction prevention layer;
removing the mold layer;
forming a dielectric layer along the storage node surface; and
forming a plate electrode over the dielectric layer, wherein the plate electrode includes stacked layers of a third reduction prevention layer, a second metal nitride carbide layer, and a capping layer.

20. The method of claim 19, wherein the first to third reduction prevention layers and the capping layer comprise metal nitride.

21. The method of claim 19, wherein the first to third prevention layers are formed of the same material as the capping layer and has a film that is denser than the capping layer.

22. The method of claim 19, wherein the first to third prevention layers and the capping layer comprise TiN.

23. The method of claim 19, wherein the first and second metal nitride carbide layers comprise TiCHN.
